(19) United States
(12) Patent Application Publication
(10) Pub. No.: US 2025/0089317 A1
(43) Pub. Date: Mar. 13, 2025

(54) NANOSHEET STRUCTURES WITH BOTTOM SEMICONDUCTOR MATERIAL

(71) Applicant: GlobalFoundries U.S. Inc., Malta, NY (US)

(72) Inventors: Hong YU, Clifton Park, NY (US); William J. TAYLOR, JR., Clifton Park, NY (US)

(21) Appl. No.: 18/463,889

(22) Filed: Sep. 8, 2023

(51) Int. Cl. H01L 29/08; H01L 29/66; H01L 29/775; H01L 29/786

(52) U.S. Cl. CPC H10D 62/151; H10D 30/014; H10D 30/031; H10D 30/43; H10D 30/6757; H10D 30/6735

(57) ABSTRACT

The present disclosure relates to semiconductor structures and, more particularly, to nanosheet transistor structures with a bottom epitaxial semiconductor material and methods of manufacture. The structure includes: a plurality of stacked semiconductor nanosheets; a plurality of gate structures surrounding individual semiconductor nanosheets of the plurality of semiconductor nanosheets; a first semiconductor material of a first conductivity type at source/drain regions of the plurality of gate structures; and a second semiconductor material of a second conductivity type above the first semiconductor material, the first conductivity type being different than the second conductivity type.

### BACKGROUND

The present disclosure relates to semiconductor structures and, more particularly, to nanosheet transistor structures with a bottom semiconductor material and methods of manufacture.

Gate-All-Around (GAA) nanosheet field effect transistors (FETs) include stacks of nanosheets or nanowires with spacers that are surrounding the full perimeter of multiple nanosheet channel regions with a metal gate stack. Nanosheet transistors have increased performance over planar transistors by providing increased device density and performance. A bottom nanosheet, though, can exhibit high leakage issues which may affect the overall performance of the transistor.

### SUMMARY

In an aspect of the disclosure, a structure comprises: a plurality of stacked semiconductor nanosheets; a plurality of gate structures surrounding individual semiconductor nanosheets of the plurality of semiconductor nanosheets; a first semiconductor material of a first conductivity type at source/drain regions of the plurality of gate structures; and a second semiconductor material of a second conductivity type above the first semiconductor material, the first conductivity type being different than the second conductivity type.

In an aspect of the disclosure, a structure comprises: a semiconductor substrate; a plurality of nanosheets interleaved with a plurality of gate structures over the semiconductor substrate; and source/drain regions adjacent to the plurality of gate structures and extending into the semiconductor substrate, the source/drain regions comprising semiconductor material extending from a bottom plane to a raised portion over the semiconductor substrate and comprising two different conductivity types.

In an aspect of the disclosure, a method comprises: forming a plurality of gate structures; forming a first semiconductor material of a first conductivity type at source/drain regions of the plurality of gate structures; and forming a second semiconductor material of a second conductivity type above the first semiconductor material, the first conductivity type being different than the second conductivity type.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a cross-sectional view of a nanosheet field effect transistor (FET) in accordance with aspects of the present disclosure.

FIGS. 2A-2F show cross-sectional views of respective fabrication processes of a nanosheet FET in accordance with aspects of the present disclosure.

### DETAILED DESCRIPTION

The present disclosure relates to semiconductor structures and, more particularly, to nanosheet transistor structures with a bottom semiconductor material and methods of manufacture. More specifically, the present disclosure comprises nanosheet transistor structures with a ball or sigma shaped cavity filled with an epitaxial semiconductor material in the bottom plane. In embodiments, the epitaxial semiconductor material may have a conductivity type that is different than the conductivity type of the source/drain regions. Advantageously, the structures described herein prevent bottom plane leakage issues.

In more specific embodiments, the structure may be a FET comprising a plurality of stacked nanosheets. A cavity may be provided under the bottom nanosheet in the source/drain regions. The cavity can be a ball shape or sigma shape, as examples. A first semiconductor material may be grown in the cavity, which is overlapping with the nanosheets (and gate structures). A second semiconductor material may be grown in the remaining portion of the cavity, over the first semiconductor material. The second semiconductor material may be used as the diffusion regions, e.g., source/drain regions, of the device. In embodiments, the first semiconductor material may be different than the second semiconductor material. For example, the first semiconductor material and the second semiconductor material may have a different conductivity type.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

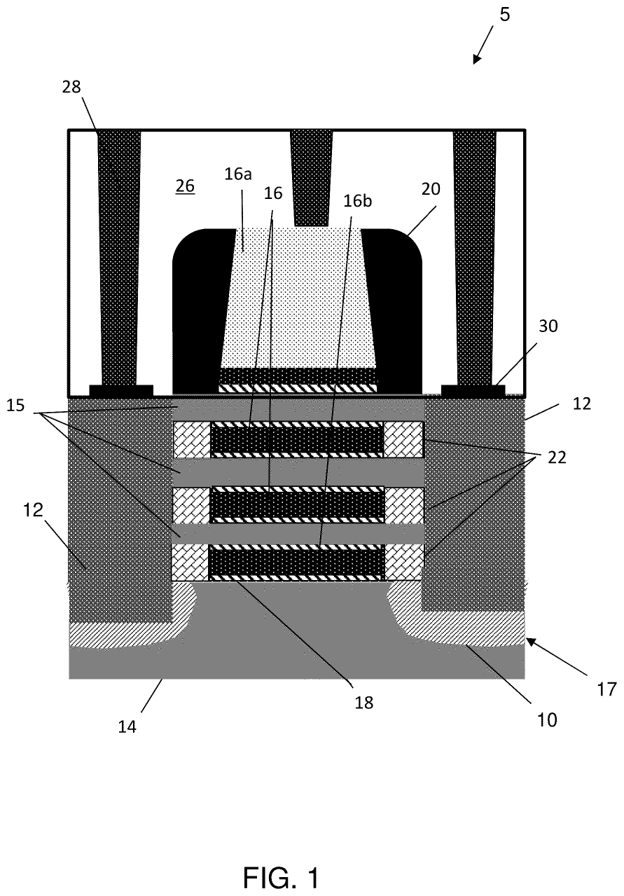

FIG. 1 shows a cross-sectional view of a structure in accordance with aspects of the present disclosure. In embodiments, the structure 5 of FIG. 1 may be a nanosheet FET comprising an epitaxial semiconductor material 10 formed in a cavity 17 of a semiconductor substrate 14. In embodiments, the cavity 17 may be, e.g., a ball shape cavity or sigma shape cavity. A semiconductor material 12 may be formed over the epitaxial semiconductor material 10 in the remaining portion of the cavity 17. The semiconductor material 12 may be raised diffusion regions of the transistor, e.g., source/drain regions of the FET. In embodiments, the semiconductor materials 10, 12 may be composed of any suitable semiconductor material including, but not limited to, Si, SiGe, SiGeC, SiC, GaAs, InAs, InP, InGaAs and other III/V or II/VI compound semiconductors.

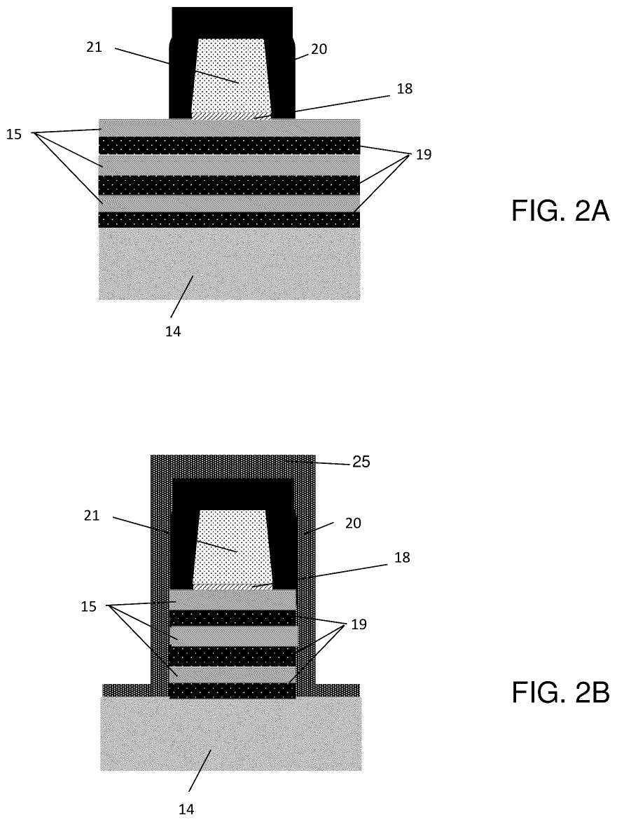

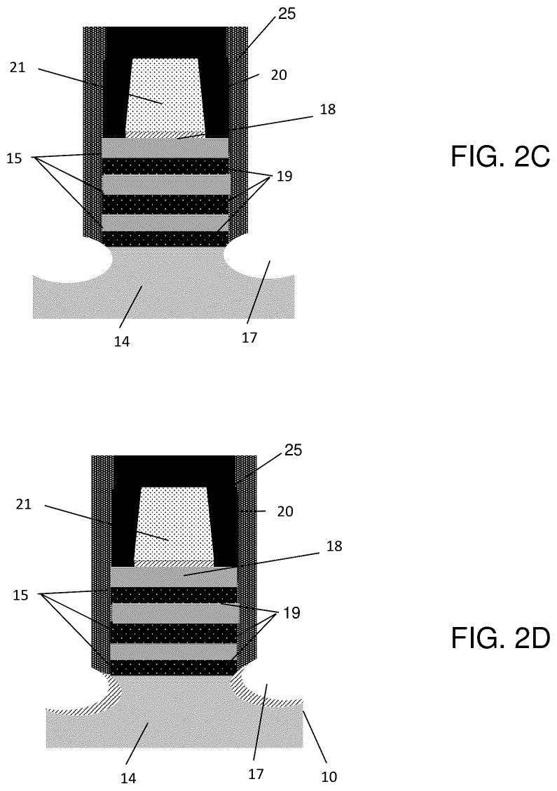

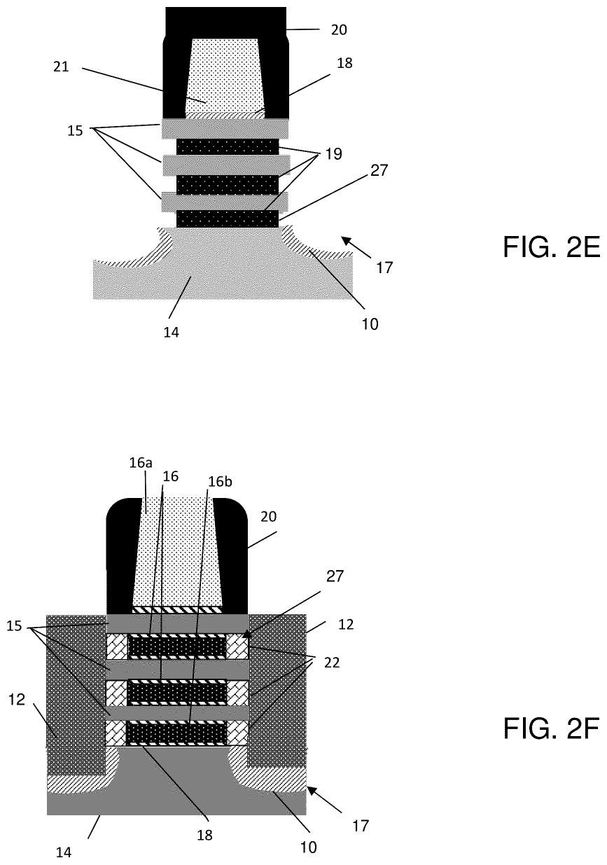

In embodiments, the semiconductor materials 10, 12 may have different conductivity types. For example, in an NFET implementation, the epitaxial semiconductor material 10 may include a P-type dopant such as Boron (B); whereas the semiconductor material 12 may include an N-type dopant, e.g., Arsenic (As), Phosphorus (P) and Antimony (Sb). Alternatively, in a PFET implementation, the epitaxial semiconductor material 10 may include an N-type dopant; whereas the semiconductor material 12 may include a P-type dopant. In preferred embodiments, the semiconductor material 10 may SiC in an NFET implementation and SiGe in a PFET implementation. As described with respect to FIGS. 2D and 2F, the different conductivity types may be provided by an epitaxial growth process with an in-situ doping or, alternatively, by an ion implantation process.

The structure 5 further includes a plurality of stacked nanosheets 15 disposed over the semiconductor substrate 14. In embodiments, each of the nanosheets 15 acts as a channel region for respective gate structures 16, 16a, 16b, which wrap around each of the stacked nanosheets 15. By way of example, in embodiments, the respective gate structures 16, 16b may be interleaved with the nanosheets 15. Although three nanosheets 15 are shown stacked together with a respective number of wraparound gate structures 16, 16b, it should be understood that more or less than three nanosheets are contemplated herein. It should further be understood by those of skill in the art that the stack of nanosheets 15 and respective gate structures 16, 16a, 16b may equally represent a fin structure for a FinFET.

The semiconductor substrate 14 and stacked nanosheets 15 may be composed of any suitable semiconductor material including, but not limited to, Si, SiGe, SiGeC, SiC, GaAs, InAs, InP, InGaAs and other III/V or II/VI compound semiconductors. The semiconductor substrate 14 and stacked nanosheets 15 may also comprise any suitable single crystallographic orientation (e.g., a (100), (110), (111), or (001) crystallographic orientation).

In embodiments, the semiconductor substrate 14 may be a single semiconducting material such as bulk substrate comprising the semiconductor materials described herein. Alternatively, the semiconductor substrate 14 may comprise semiconductor on insulator technology. The semiconductor on insulator technology may include, from bottom to top, a handle wafer, an insulator layer and the semiconductor substrate 14 on top of the insulator layer. The insulator layer may comprise any suitable material, including silicon oxide, sapphire, other suitable insulating materials, and/or combinations thereof. An exemplary insulator layer may be a buried oxide layer (BOX). The insulator layer is formed by any suitable process, such as separation by implantation of oxygen (SIMOX), oxidation, deposition, and/or other suitable processes. The handle wafer may comprise any suitable semiconductor material as already described herein, and may be used as a support for the insulator layer and the semiconductor substrate 14.

Still referring to FIG. 1, a gate structure 16a may be provided on an upper nanosheet, with wraparound gate structures 16, 16b wrapping around respective nanosheets 15. The lower gate structure 16b may be provided over the semiconductor substrate 14. The gate structures 16, 16a, 16b may be metal gate structures composed of appropriate workfunction metals. For example, the workfunction material may include, for example, Ti, TiAlC, Al, TiAl, TaN, TiN, TiC, Co, TiC, TaC, HfTi, TiSi, or TaSi. The workfunction material may be formed by CVD, physical vapor deposition (PVD), including sputtering, atomic layer deposition (ALD) or other suitable method as is known in the art. Alternatively, the gate structures 16, 16a, 16b may be polysilicon material.

The gate structures 16, 16a, 16b include gate dielectric material 18 surrounding each of the nanosheets 15 and over the semiconductor substrate 14. The gate dielectric material 18 may be high-k dielectric material provided on a surface of the semiconductor substrate 14, and which wraps around respective nanosheets 15. In embodiments, the high-k dielectric material may be, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof.

Still referring to FIG. 1, a sidewall spacer 20 surrounds the gate structure 16a and inner sidewall spacers 22 surround the respective wraparound gate structures 16, 16b. The inner sidewall spacers 22 may be provided between the nanosheets 15, in addition to between the lowest nanosheet and the semiconductor substrate 14. The cavity 17 may extend underneath the inner sidewall spacers 22. The sidewall spacer 20 may be SiN, for example. The inner sidewall spacers 22 may also be composed of SiN or other low-k dielectric materials such as SiOCN, SiBCN, etc. The inner sidewall spacers 22 may be used to isolate the diffusion regions, e.g., semiconductor material 12, from the gate structures 16, 16b.

FIG. 1 further shows the semiconductor material 12 formed in the cavity 17 of the semiconductor substrate 14 and within the source/drain regions. In embodiments, the semiconductor material 12 may overlap with the gate structures 16, 16a, 16b. For example, the semiconductor material 12 may extend underneath the gate structures 16, 16b. The semiconductor material 12 may be epitaxially grown from the semiconductor substrate 14. Raised diffusion regions composed of the semiconductor material 12 may be epitaxial semiconductor material, selectively grown from the semiconductor material 10 and the stacked nanosheets 15. As already noted herein, the raised source/drain regions 12 may be isolated from the gate structures 16, 16b by the inner sidewall spacers 22.

In embodiments, the semiconductor materials 10, 12 may be, for example, Si or SiGe or SiP with different conductivity types as described herein. For example, the source/drain regions 12 may be in-situ doped with an appropriate dopant for an NFET device or PFET device as is understood by those of skill in the art and as already described in the present disclosure. Alternatively, the semiconductor materials 10, 12 may be subjected to an ion implantation process as is known in the art, with opposite dopant concentrations.

Still referring to FIG. 1, interlevel dielectric material 26 may be deposited over the structures, with contacts 28 formed to the gate structure 16a, 16, 16b and the raised source/drain regions 12. In embodiments, the interlevel dielectric material 26 may be an oxide material, nitride material, or combination of layers of the oxide and nitride materials. Prior to forming the contacts to the raised source/drain regions 12, a silicide process may be performed to form silicide contacts 30 on the raised source/drain regions 12 as described further herein.

FIGS. 2A-2F show cross-sectional views of respective fabrication processes of a nanosheet FET in accordance with aspects of the present disclosure. For example, FIG. 2A shows the nanosheets 15 stacked on the semiconductor substrate 14, alternating with sacrificial semiconductor layers 19 between the nanosheets 15. In embodiments, the sacrificial semiconductor layers 19 may be any sacrificial semiconductor material that is selective to the semiconductor material of the nanosheets 15. For example, the sacrificial semiconductor layers 19 may be SiGe; whereas the nanosheets 15 may be Si. The sacrificial semiconductor layers 19 and the nanosheets may be deposited by an epitaxial growth process as is known in the art such that no further explanation is required for a complete understanding of the present disclosure.

Still referring to FIG. 2A, a gate dielectric material 18 may be deposited on the top nanosheet, followed by a sacrificial gate material 21. In embodiments, the gate dielectric material 18 may be any high-k or low-k gate dielectric material, depending on the performance characteristics of the device. The sacrificial gate material 21 may be polysilicon material, for example. The gate dielectric material 18 and the sacrificial gate material 21 may be deposited by conventional deposition processes, e.g., chemical vapor deposition (CVD), atomic layer deposition (ALD), plasma enhanced CVD (PECVD), etc., followed by a conventional patterning process using lithography and etching processes as is known in the art such that no further explanation is required for a complete understanding of the present disclosure. The conventional patterning process will form a sacrificial gate structure.

FIG. 2A further shows a spacer material 20 formed over the sacrificial gate structure. In embodiments, the spacer material 20 may be a nitride material formed by a conventional deposition process, e.g., CVD, followed by a patterning process to expose portions of the top nanosheet 15. In embodiments, the spacer material 20 may be a sidewall spacer for a subsequently formed gate structure.

In FIG. 2B, the stack of nanosheets 15 and sacrificial semiconductor layers 19 are patterned. For example, in embodiments, the stack of nanosheets 15 and sacrificial semiconductor layers 19 may be patterned using a conventional reactive ion etching (RIE) process as is known in the art. In this process, the spacer material 20 may be used as a mask in the etching process to protect the sacrificial gate structure. Following the patterning process, a sacrificial mask 25 may be deposited over the structures. The sacrificial mask 25 may be an oxide material as an example. In additional examples, the sacrificial mask 25 may be a material that is different than the spacer material 20. The sacrificial mask 25 may be blanket deposited using a conventional CVD process.

As further shown in FIG. 2C, the sacrificial mask 25 may be removed over the semiconductor substrate 14 and the top of the sacrificial gate structure. In embodiments, the sacrificial mask 25 may be removed by an anisotropic etching process, which will expose the underlying semiconductor substrate 14 in the source/drain regions.

The cavity 17 may be formed in the exposed underlying semiconductor substrate 14 in the source/drain regions. The cavity 17 may be formed by a RIE process. In embodiments, the cavity 17 may be a ball shape or sigma shape within the semiconductor substrate 14 in the source/drain regions and, in embodiments, extends under the nanosheets 15 (and yet to be formed gate structures). In this process, the sacrificial mask 25 will protect the underlying sacrificial gate structure.

In FIG. 2D, the semiconductor material 10 will partially fill the cavity 17 in the source/drain regions. In embodiments, the semiconductor material 10 may be epitaxially grown semiconductor material, with an in-situ doping. In embodiments, for example, in an NFET implementation, the epitaxial semiconductor material 10 may include a P-type dopant such as Boron (B); whereas, in a PFET implementation, the epitaxial semiconductor material 10 may include an N-type dopant, e.g., Arsenic (As), Phosphorus (P) and Antimony (Sb).

In an alternative approach, a dopant of a particular conductivity type for the epitaxial semiconductor material 10 may be introduced by, for example, ion implantation process. In this process, a patterned implantation mask may be used to define selected areas exposed for the implantation. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions.

In FIG. 2E, the sacrificial mask 25 is removed, exposing the stack of nanosheets 15 and sacrificial semiconductor layers 19. A selective etching process may be performed to form recesses 27 in the sacrificial semiconductor layers 19 between the stack of nanosheets 15.

As shown in FIG. 2F, inner sidewall spacers 22 are formed in the recesses 27. In embodiments, the inner sidewall spacers 22 may be composed of SiN or other low-k dielectric materials such as SiOCN, SiBCN, etc. The inner sidewall spacers 22 may be deposited by a conventional deposition process, e.g., CVD.

FIG. 2F further shows the remaining sacrificial semiconductor layers 19 may be removed by a conventional selective etching process. The sacrificial gate material 21 may also be removed by a selective etching process, e.g., RIE. The respective gate structures 16, 16a, 16b and accompanying gate dielectric material 18 may be deposited between and above the stacked nanosheets 15 using conventional deposition methods, e.g., CVD, ALD, PECVD, etc.

Still referring to FIG. 2F, the semiconductor material 12 may be epitaxially grown in the remaining portions of the cavity 17 and along the sides of the inner sidewall spacers 22 and nanosheets 15, e.g., source/drain regions. In embodiments, the semiconductor material 12 may be epitaxially grown from the nanosheets 15 and the epitaxial semiconductor material 10, with an in-situ doping process. Alternatively, the dopant may be provided by an ion implantation process, as already described herein. The conductivity type of the dopant will be opposite to that of the epitaxial semiconductor material 10. The semiconductor material 12 will be used to form raised source/drain regions.

Referring back to FIG. 1, an interlevel dielectric material 26 may be deposited over the structure, e.g., gate structures 16, 16a, 16b and source/drain regions, e.g., semiconductor material 12. The interlevel dielectric material 26 may be an oxide material, nitride material or combination thereof, deposited by a CVD process as an example. Trenches may be formed in the interlevel dielectric material 26 to expose the underlying source/drain regions, e.g., semiconductor material 12 and gate structure 16a. The trenches may be formed by conventional lithography and etching (RIE) processes as is known in the art.

Prior to forming the contacts to the raised source/drain regions 12 and gate structures 16, 16a, 16b (should the gate structure be composed of polysilicon), a silicide process may be performed to form silicide contacts on the raised source/drain regions 12. As should be understood by those of skill in the art, the silicide process begins with deposition of a thin transition metal layer, e.g., nickel, cobalt or titanium, over fully formed and patterned semiconductor devices (e.g., source/drain regions 12). After deposition of the material, the structure is heated allowing the transition metal to react with exposed silicon (or other semiconductor material as described herein) in the active regions of the semiconductor device (e.g., source/drain region) forming a low-resistance transition metal silicide. Following the reaction, any remaining transition metal is removed by chemical etching, leaving silicide contacts 30 in the active regions of the device. It should be understood by those of skill in the art that silicide contacts will not be required on the metal gate structures.

Following the silicide process, the contacts 28 may be formed by conventional deposition processes within the vias or trenches, followed by a planarization process (e.g., chemical mechanical planarization (CMP). In embodiments, the contacts 28 may be tungsten or other appropriate metal material, e.g., aluminum, copper, etc. A TiN or TaN liner may also be used prior to the deposition of the tungsten. It should be recognized by those of skill in the art that contacts will be provided to each of the gate structures 16, 16a, 16b. In the case of gate structures 16, 16b, it should be understood by those of ordinary skill in the art that such gate structures, in another cross-sectional view, will extend beyond the nanosheets 14 for the contacts 28 to electrically connect to the gate structures 16, 16b.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a plurality of semiconductor nanosheets;
a plurality of gate structures surrounding individual semiconductor nanosheets of the plurality of semiconductor nanosheets;
a first semiconductor material of a first conductivity type at source/drain regions of the plurality of gate structures; and
a second semiconductor material of a second conductivity type above the first semiconductor material, the first conductivity type being different than the second conductivity type.

2. The structure of claim 1, wherein the first semiconductor material and the second semiconductor material are in a cavity of a semiconductor substrate.

3. The structure of claim 2, wherein the first semiconductor material is at a bottom of the cavity and the second semiconductor material fills a remaining portion of the cavity.

4. The structure of claim 3, wherein the second semiconductor material comprises raised diffusion regions on sides of the plurality of gate structures.

5. The structure of claim 2, wherein the cavity is ball shaped.

6. The structure of claim 2, wherein the cavity is sigma shaped.

7. The structure of claim 1, wherein the plurality of gate structures include inner spacers between the plurality of semiconductor nanosheets.

8. The structure of claim 7, wherein the first semiconductor material extends under the inner spacers.

9. The structure of claim 1, wherein the plurality of semiconductor nanosheets are interleaved with the plurality of gate structures and the first semiconductor material extends underneath the plurality of gate structures.

10. The structure of claim 1, wherein in an NFET, the first conductivity type of the first semiconductor material includes a P-type dopant and the second conductivity type of the second semiconductor material includes an N-type dopant.

11. The structure of claim 1, wherein in an PFET, the first conductivity type of the first semiconductor material includes an N-type dopant and the second conductivity type of the second semiconductor material includes a P-type dopant.

12. A structure comprising:
a semiconductor substrate;
a plurality of nanosheets interleaved with a plurality of gate structures over the semiconductor substrate; and
source/drain regions adjacent to the plurality of gate structures and extending into the semiconductor substrate, the source/drain regions comprising semiconductor material extending from a bottom plane to a raised portion over the semiconductor substrate and comprising two different conductivity types.

13. The structure of claim 12, wherein the semiconductor material comprises a first semiconductor material with a first conductivity type and a second semiconductor material with a second conductivity type.

14. The structure of claim 13, wherein the first semiconductor material extends under the plurality of gate structures in a cavity of the semiconductor substrate.

15. The structure of claim 14, wherein the second semiconductor material comprises raised diffusion regions on sides of the plurality of gate structures.

16. The structure of claim 14, wherein the cavity is one of a ball shaped and sigma shaped.

17. The structure of claim 12, wherein the plurality of gate structures are interleaved with the plurality of nanosheets, the plurality of gate structures include inner spacers between the plurality of nanosheets, and the semiconductor material extends under the inner spacers.

18. The structure of claim 12, wherein in an NFET, a bottom portion of the semiconductor material comprises a P-type dopant and an upper portion of the semiconductor material comprises an N-type dopant.

19. The structure of claim 12, wherein in a PFET, a bottom portion of the semiconductor material comprises an N-type dopant and an upper portion of the semiconductor material comprises a P-type dopant.

20. A method comprising:
forming a plurality of gate structures;
forming a first semiconductor material of a first conductivity type at source/drain regions of the plurality of gate structures; and
forming a second semiconductor material of a second conductivity type above the first semiconductor material, the first conductivity type being different than the second conductivity type.
